(19) United States
(12) Patent Application Publication
(10) Pub. No.: US 2006/0126291 A1
(43) Pub. Date: Jun. 15, 2006

(54) Fan-driven heat dissipating device with enhanced air blowing efficiency

(75) Inventor: Shu-Ju Lin, Taipei (TW)

Correspondence Address: PEARL COHEN ZEDEK, LLP, 1500 BROADWAY 12TH FLOOR, NEW YORK, NY, 10036, US

(73) Assignee: INVENTEC CORPORATION

(21) Appl. No.: 11/010,265

(22) Filed: Dec. 14, 2004

(51) Int. Cl. H05K 7/20

(52) U.S. Cl. 361/695

(57) ABSTRACT

A fan-driven heat dissipating device with an enhanced air blowing efficiency is provided, which is designed for use in conjunction with a casing of an electronic system, such as a server, for providing the server with a fan-driven heat-dissipating function, and which is characterized by the provision of a special casing structure that allows the maximum allowable blade length of the fan unit to be increased as compared to the prior art, allowing the fan unit to provide an enhanced air blowing efficiency so that it can more efficiently blow away the heat produced by the server during operation.

### BACKGROUND OF THE INVENTION

1. Field of the Invention

This invention relates to heat dissipating technology, and more particularly, to a fan-driven heat dissipating device which is designed for use in conjunction with a casing of an electronic system, such as a 1U server, for providing the server with a fan-driven heat-dissipating function that provides a more enhanced heat-dissipating efficiency than prior art for the purpose of more efficiently blowing away the heat produced by the server during operation.

2. Description of Related Art

Electronic systems, such as servers, are typically installed with a fan-driven heat dissipating device for dissipating the heat generated by the internal circuitry (such as CPU) of the server system for the purpose of protecting the server system from overheat damage.

FIG. 1 is a schematic diagram showing a sectional view of a conventional fan-driven heat dissipating device 100 after being installed to a server casing 10. As shown, this conventional fan-driven heat dissipating device 100 comprises an exterior casing 110 and a fan unit 120, where the exterior casing 110 is substantially squarely shaped in cross section and formed with a hollowed enclosure space 111 for accommodating the fan unit 120.

As illustrated in FIG. 1, in a practical example of application, the server casing 10 provides the fan-driven heat dissipating device 100 with an installation space of a height of about 40.5 mm for installing the conventional fan-based heat dissipating device 100 therein, and the squarely-shaped exterior casing 110 has a side length of about 40 mm, the circularly-shaped enclosure space 111 has a diameter of about 38 mm, and the thinnest part of the side wall of the exterior casing 110 is about 0.8 mm. Under this specification, since the fan unit 120 is separated from the side wall of the exterior casing 110 by a distance of only about 0.3 mm, the maximum allowable blade length of the fan unit 120 is only about 18.9 mm.

In practical application, however, one drawback to the aforesaid conventional fan-driven heat dissipating device 100 is that, since the fan unit 120 is very small in size with a maximum allowable blade length of about 18.9 mm, it can provide only an unsatisfactory air blowing efficiency that results in a low heat dissipating efficiency.

### SUMMARY OF THE INVENTION

It is therefore an objective of this invention to provide a new and improved fan-driven heat dissipating device which is capable of providing a more enhanced air blowing efficiency than the prior art so as to be capable of providing a higher heat-dissipating efficiency than the prior art.

The fan-driven heat dissipating device according to the invention is designed for use in conjunction with a casing of an electronic system, such as a 1U server, for providing the server with a fan-driven heat-dissipating function that provides a more enhanced heat-dissipating efficiency than prior art for the purpose of more efficiently blowing away the heat produced by the server during operation.

Structurally, the fan-driven heat dissipating device according to the invention comprises: (a) a pair of exterior covering members, each of which has a side wall with a first surface and a second surface on opposite ends of the side wall, and which are separated oppositely by a predetermined distance so as to provide an enclosure space therebetween; (b) a pair of enforcement members, which are respectively attached to the first surface and the second surface of the exterior covering members for securely combining the two exterior covering members into one integral body; and (c) a fan unit, which is accommodated within the enclosure space confined by the two exterior covering members for providing an air-blowing function.

The fan-driven heat dissipating device according to the invention is characterized by the provision of a special casing structure that allows the maximum allowable blade length of the fan unit to be increased as compared to the prior art, allowing the fan unit to provide an enhanced air blowing efficiency so that it can more efficiently blow away the heat produced by the server during operation.

### BRIEF DESCRIPTION OF DRAWINGS

The invention can be more fully understood by reading the following detailed description of the preferred embodiments, with reference made to the accompanying drawings, wherein:

FIG. 1 is a schematic diagram showing a sectional view of a conventional fan-driven heat dissipating device after being installed to a server casing;

FIG. 2A is a schematic diagram showing an exploded perspective view of the fan-driven heat dissipating device according to the invention;

FIG. 2B is a schematic diagram showing a sectional view of the fan-driven heat dissipating device of the invention after being combined and installed to a server casing; and

FIG. 3 is a schematic diagram showing a sectional view of another embodiment of the fan-driven heat dissipating device according to the invention.

### DETAILED DESCRIPTION OF PREFERRED EMBODIMENTS

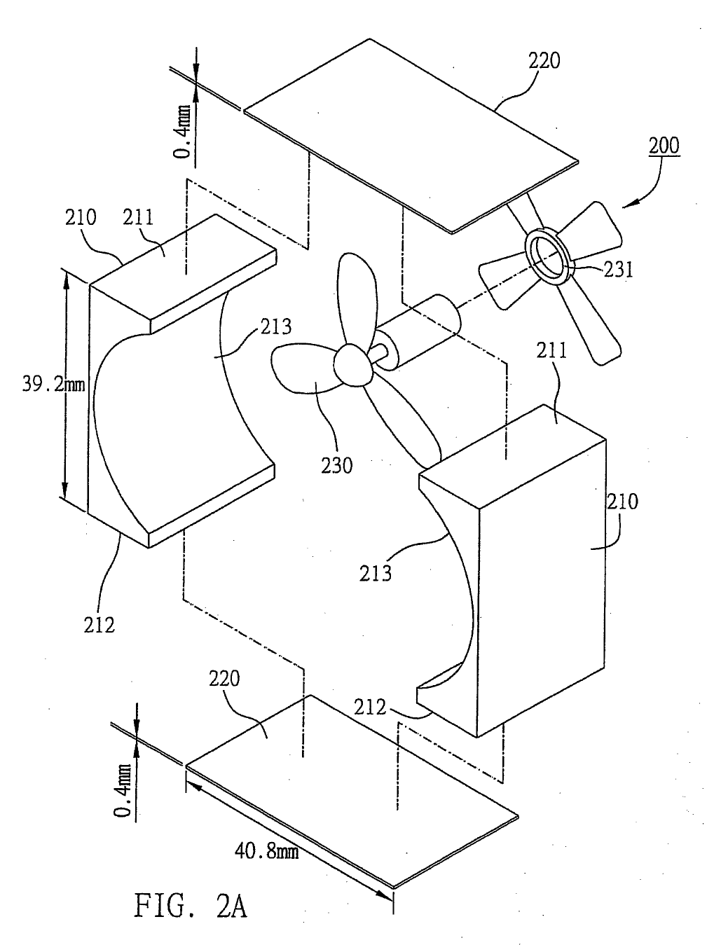

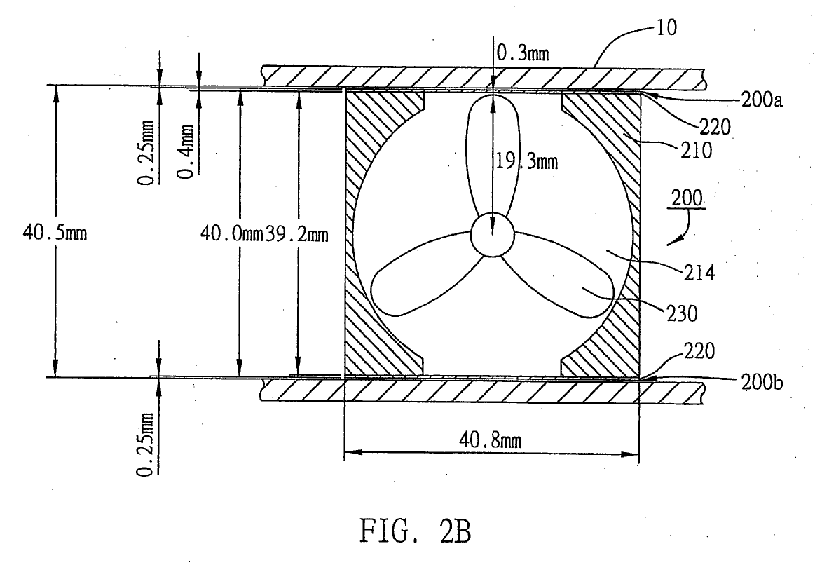

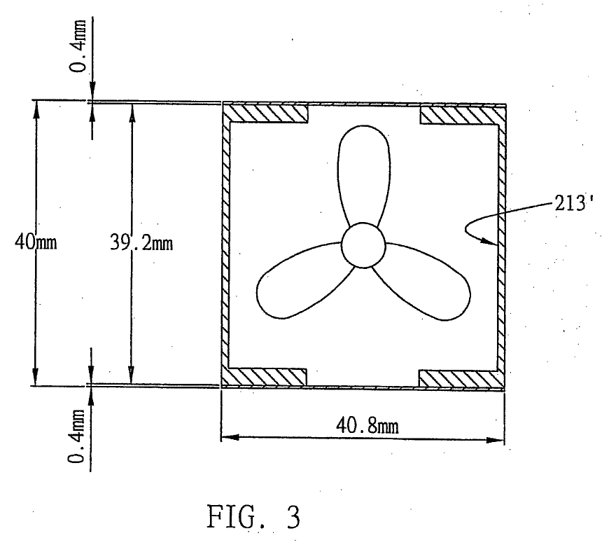

The fan-driven heat dissipating device according to the invention is disclosed in full details by way of preferred embodiments in the following with reference to FIGS. 2A-2B and FIG. 3.

FIG. 2A is a schematic diagram showing an exploded perspective view of the fan-driven heat dissipating device of the invention 200. As shown, the fan-driven heat dissipating device of the invention 200 comprises: (a) a pair of exterior covering members 210; (b) a pair of enforcement members 220; and (c) a fan unit 230.

The two exterior covering members 210 are each formed with a side wall 213 with a first surface 211 and a second surface 212 on opposite ends thereof. In practical implementation, the side wall 213 can be either a concave surface as illustrated in FIGS. 2A-2B, or alternatively a flat surface 213′ as illustrated in FIG. 3. Further, the side wall 213 is attached with a ribbed fixation member 231 for use to hold the fan unit 230 in position when combined. In assembly, the two exterior covering members 210 are separated oppositely by a predetermined distance so as to provide an enclosure space 214 between the side walls 213 thereof. In the embodiment shown in FIGS. 2A-2B, for example, the combined body of the two exterior covering members 210 has a width of 40.8 mm and a height of 39.2 mm, and the thinnest part of the side wall 213 has a thickness of 0.8 mm.

The enforcement members 220 are preferably made of a rigid and shock-resistant material, such as a magnesium alloy. In assembly, these two enforcement members 220 are respectively attached to the first surface 211 and the second surface 212 of the exterior covering members 210 for securely combining the two exterior covering members 210 into one body. In this embodiment, for example, the enforcement members 220 each have a width of 40.8 mm and a thickness of 0.4 mm.

The fan unit 230 is secured by means of a ribbed fixation member 231 to the side walls 213 of the exterior covering members 210 for installation within the enclosure space 214 confined by the two exterior covering members 210 as shown in FIG. 2B for providing an air-blowing function.

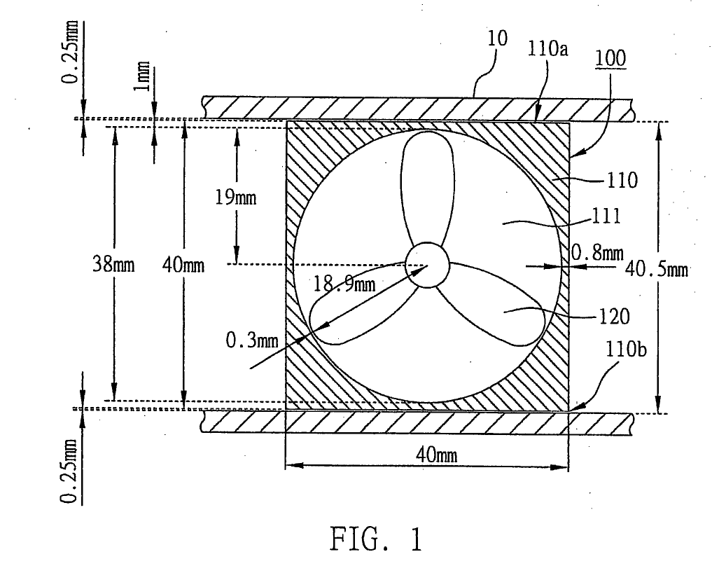

As shown in FIG. 2B, after the fan-driven heat dissipating device of the invention 200 has been assembled, the height thereof is still 40.0 mm, which is the same as the prior art shown in FIG. 1, but the height of the enclosure space 214 is increased to 39.2 mm (the prior art of FIG. 1 is only 38 mm). As a result, if the fan unit 230 and the side wall 213 of the exterior covering members 210 is separated by a distance of 0.3 mm, it allows the fan unit 230 to have a maximum allowable blade length of (39.2−0.3*2)/2=19.3 mm (the prior art of FIG. 1 is only 18.9 mm). Therefore, after the fan-driven heat dissipating device of the invention 200 has been installed in position onto the server casing 10, the topmost surface 200a and the bottommost surface 200b is still separated from the server casing 10 by a distance of 0.25 mm as the prior art. However, since the maximum allowable 19.3 mm blade length of the fan unit 230 is greater than the 18.9 mm maximum allowable blade length of the prior art of FIG. 1, it allows the fan unit 230 to provide an enhanced air blowing efficiency as compared to the prior art, thereby allowing the fan unit 230 to provide a higher heat-dissipating efficiency than prior art that can more efficiently blow away the heat generated by the electronic circuitry (not shown) on the server casing 10.

In conclusion, the invention provides a fan-driven heat dissipating device which is designed for use in conjunction with a casing of an electronic system, such as a 1U server, for providing the server with a fan-driven heat-dissipating function, and which is characterized by the provision of a special casing structure that allows the maximum allowable blade length of the fan unit to be increased as compared to the prior art, allowing the fan unit to provide an enhanced air blowing efficiency so that it can more efficiently blow away the heat produced by the server during operation. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A fan-driven heat dissipating device for use with a casing of an electronic system for providing the electronic system with a fan-driven heat dissipating function;
the fan-driven heat dissipating device comprising:
a pair of exterior covering members, each of which has a side wall with a first surface and a second surface on opposite ends of the side wall, and which are separated oppositely by a predetermined distance so as to provide an enclosure space therebetween;
a pair of enforcement members, which are respectively attached to the first surface and the second surface of the exterior covering members for combining the two exterior covering members into one integral body; and
a fan unit, which is accommodated within the enclosure space confined by the two exterior covering members for providing an air-blowing function.

2. The fan-driven heat dissipating device of claim 1, wherein the electronic system is a server.

3. The fan-driven heat dissipating device of claim 1, wherein the enforcement members are each made of a shock-resistant material.

4. The fan-driven heat dissipating device of claim 3, wherein the shock-resistant material is a magnesium alloy.

5. The fan-driven heat dissipating device of claim 1, wherein the side wall between the first surface and the second surface on each of the exterior covering members is formed into a concave surface.

6. The fan-driven heat dissipating device of claim 1, wherein the side wall between the first surface and the second surface on each of the exterior covering members is formed into a flat surface.
